(19) United States
(12) Patent Application Publication
(10) Pub. No.: US 2025/0353961 A1
(43) Pub. Date: Nov. 20, 2025

(54) METHOD FOR EXTENSION OF THE SHELF LIFE OF POSITIVE TYPE PHOTOSENSITIVE POLYIMIDE PRECURSORS IN SOLUTION

(71) Applicant: Akron Polymer Systems, Inc., Akron, OH (US)

(72) Inventors: Yufeng Zhu, Highland Heights, OH (US); Lang Hu, Tallmadge, OH (US); Zhen Li, Hudson, OH (US); Limin Sun, Copley, OH (US); Dong Zhang, Hudson, OH (US); Xiaoliang Zheng, Hudson, OH (US)

(21) Appl. No.: 18/667,193

(22) Filed: May 17, 2024

(51) Int. Cl. C08G 73/10; C08K 3/16; C08K 3/30; G03F 7/004; G03F 7/038; G03F 7/039; H10K 50/84

(52) U.S. Cl. CPC C08G 73/1067; C08G 73/1032; C08K 3/16; C08K 3/30; G03F 7/0046; G03F 7/0387; G03F 7/0392; H10K 50/84; C08K 2003/309

(57) ABSTRACT

This invention discloses a method for extending the shelf life of polyamic ester (PAE) solutions during the manufacturing of positive-type photosensitive polyimide (PSPI) precursor resins. With the addition of certain acids within a specified loading range to the reaction solution after the acetal esterification reaction, the shelf of the PAE solution can be significantly increased by decreasing the rate of imidization. The acid additive may consume part or all of the impurities generated from the acetal esterification reaction, which improves the stability of the PAE polymer. This invention substantially improves the feasibility and manufacturing cost of positive-type PSPI precursor polymers.

### FIELD OF THE INVENTION

This invention is related to the semiconductor and display technology fields, specifically, a method for extending the shelf life of a PAE solution during the manufacturing of a positive type photosensitive polyimide precursor resin.

### BACKGROUND OF THE INVENTION

Photosensitive polyimides (PSPI) exhibited both the advantages of high-performance polyimides as well as the photolithography capability of photoresists and have become a key component in the manufacturing of semiconductor and display devices. The i-line photolithography process typically includes film coating, prebaking, photo exposure, post-exposure baking, developing, and final cure processes. In order to have good film forming and dissolution properties, PSPI precursors are often used, which will be further converted to a polyimide after final curing [U.S. Pat. No. 9,897,915B2]. Although the polyamic acid (PAA) is the most straightforward precursor for polyimides, their solubility is often too high in alkaline developers for positive-type PSPIs to create sufficient contrast between exposed and non-exposed regions [U.S. Pat. No. 8,758,976B2]. After converting the PAA to its corresponding polyamic ester (PAE) in a controlled manner, the amount of acid groups left in the polymer chain is adjustable, which gives the PSPI precursor film controllable solubility during the lithographic process. The acetal method has been proven to be the best method among many esterification processes owing to its high conversion, mild conditions, and commercially available starting materials [WO2016047483A1 and CN112876679A]. Unfortunately, imidization side reactions are inevitable during the acetal esterification reaction [Polym J 41, 604-608 (2009)]. A high degree of imidizaiton (DI) will cause issues such as compromised adhesion and dissolution properties during lithography. Though not often reported, the DI will further increase after the acetal esterification reaction, especially at elevated temperatures. Since the solid PAE polymer appears to be stable, it is possible to limit the DI while keeping the degree of esterification in a proper range by very quickly finishing the workup process immediately after the reaction, e.g. within 20 minutes (min). However, in high-volume manufacturing, this is almost impossible and would require a lot more capital cost in the manufacturing process. Unexpectedly, it was found that the addition of certain acids within a specified loading range to the reaction solution after the acetal esterification reaction would significantly decrease the rate of imidization and extend the shelf life of the PAE solution. This invention substantially improves the feasibility and manufacturing cost of the positive-type PSPI precursor polymers.

### SUMMARY OF THE INVENTION

This patent discloses a method to extend the shelf life of positive-type PSPI precursors in solution by the addition of acid. After potentially consuming the impurities that can cause further imidization, the DI growth becomes significantly slower or negligible under certain conditions, allowing for a longer shelf life and processing window for the PSPI precursor manufacturing.

Other methods, features and/or advantages is, or will become, apparent upon examination of the following Figures and detailed description. It is intended that all such additional methods, features, and advantages be included within this description and be protected by the accompanying claims.

### BRIEF DESCRIPTION OF THE DRAWINGS

FIG. 1 represents a typical ¹H NMR spectrum for a 6FDA-6FAPDA polymer in DMSO-d₆.

FIG. 2 represents a typical ¹H NMR spectrum for an ODPA-PFMB polymer in DMSO-d₆.

### DETAILED DESCRIPTION OF THE INVENTION

The invention discloses a method to extend the shelf life of positive-type PSPI precursors in solution by the addition of one or a combination of acids that have a pKₐ(1) less than 2.1, or preferably less than 1.0, or more preferably less than 0 in the loading range of 1 mol %-100 mol % based on the charged amount of N,N-dimethylformamide dimethyl acetal (DMFDMA), preferably in the range of 1.8 mol %-36 mol %, or more preferably 2 mol %-10 mol %. This acid additive improves the shelf life of the PSPI precursor, namely the PAE solution, by slowing down the imidization after esterification with an acetal, e.g., DMFDMA or N,N-dimethylformamide diethyl acetal (DMFDEA). The dry PAE polymer showed good DI stability after the typical workup process. However, the DI of the pristine solution after acetal esterification was found to be not stable, especially at elevated temperatures. The DI of the polymer keeps increasing, which may negatively affect properties of the PSPI precursor, such as adhesion and solubility among others. The acid additive is believed to consume part or all of the impurities generated from the acetal esterification reaction, which in turn improves the stability of the PAE polymer. In order to achieve that, the acid has to be of sufficient strength and in the specified loading ranges. Requirements for the acid or combination of acids are 1) the pKₐ(1) is less than 2.1, preferably less than 1.0, more preferably less than 0, or an number within the range between 0.01 and 2.1, for example 0.035 or 1.0 and 2) in the loading range of 1 mol %-100 mol % based on the charged amount of DMFDMA, preferably 1.8 mol %-36 mol %, more preferably 2 mol %-10 mol %, or any single number found within the range between 2 mol % and 10 mol % such as 7.5 mol %.

Specifically, the PAE solution is prepared from the esterification of a PAA in solution with an acetal, including but not limited to DMFDMA and DMFDEA. The PAA is made by a condensation reaction, preferably a condensation reaction between aromatic diamines and dianhydrides.

The aromatic dianhydride to make the PAA in this invention includes but not limited to one or a combination of 4, 4′-(hexafluoroisopropylidene)-diphthalic anhydride (6FDA), 4, 4′-oxydiphthalic anhydride (ODPA), pyromellitic dianhydride (PMDA), 3, 3′, 4, 4′-biphenyltetracarboxylic dianhydride (BPDA), 2,3,3,4-biphenyl tetracarboxylic dianhydride (a-BPDA), 3, 3′, 4, 4′-benzophenonetetracarboxylic dianhydride (BTDA), bis [4-(3,4-dicarboxyphenoxy)phenyl]propane dianhydride (BisADA), 4, 4′-(ethyne-1, 2-diyl) diphthalic anhydride (EDDPA), 3, 3′, 4, 4′-diphenylsulfonetetracarboxylic dianhydride (DSDA), 4, 4′-binaphthyl-1, 1′, 8, 8′-tetracarboxylic dianhydride (BNDA), and 1, 4, 5, 8-naphthalene-tetracarboxylic dianhydride (NDA).

The aromatic diamine to make the PAA in this invention includes but not limited to one or a combination of 2, 2′-bis(trifluoromethyl)benzidine (PFMB), 2, 2-bis(3-(3-aminobenzoylamino)-4-hydroxyphenyl) hexafluoropropane (6FAPDA), 2, 2-bis(3-amino-4-hydroxyphenyl) hexafluoropropane (6FAP), 2, 2-bis(3-(3-aminobenzoylamino)-4-hydroxyphenyl) hexafluoropropane (6FAPDA), p-phenylenediamine (PDA), 4, 4′-oxydianiline (4,4′-ODA), 3,4′-oxydianiline (3,4′-ODA), 4,4′-methylenebis(2,6-dimethylaniline) (D03), 4,4′-(1,3-phenylenedioxy)dianiline, 4,4′-[[1,1′-Biphenyl]-4,4′-diylbis(oxy)]bis[3-(trifluoromethyl)aniline](6FAPBP), 2,2-bis[4-(4-aminophenoxy)phenyl]hexafluoropropane (HFBAPP), bis(4-aminophenyl) sulfone (BSDA), bis[4-(3-aminophenoxy)phenyl]sulfone (M-BAPS), 2, 4-diaminomesitylene (DAM), 1, 5-naphthalenediamine (DAN), 1, 1′-binaphthalene-5, 5′-diamine (DABN), 3, 5-diethyl-toluene-2, 6-diamine (2, 6-DETDA), 3, 5-diethyl-toluene-2, 4-diamine (2, 4-DETDA), and 4, 4′-(9-fluorenylidene) dianiline (FRDA).

### Synthesis of PAE

First mix the dianhydride and diamine in a solvent and allow the condensation polymerization to occur at 0° C.-70° C. for 1 h-12 h. Then, an amine or anhydride compound can be added to end cap the PAA at 0° C.-70° C. for 1 h-12 h. The solvent can be one or a mixture of solvents such as, but not limited to, N-methylpyrrolidone (NMP), gama-butyrolactone (GBL), N, N-dimethylacetamide (DMAc), and N, N-dimethylformamide (DMF). The amount of solvent can be 1-10 times the weight of the solids. Heat the prepared PAA with acetal esterification reagents to convert the carboxylic acid groups to ester groups. The degree of esterification can be 10%-90%, and the esterification temperature can be 20° C.-80° C., while the esterification time can be 15 min-30 min. Esterification reagents are acetal compounds, such as, but not limited to, DMFDMA or DMFDEA, with a carboxylic acid to esterification reagent molar ratio of 1:0.1-10.

### Molecular Weights (MWs) of PAE:

Low MWs are typically needed for high-resolution positive tone photolithography. MWs of the PAE is usually controlled by adjusting the dianhydride and diamine molar ratio. By way of example and without limitation, the MWs of the polymers in the present disclosure are generally considered to have a weight-averaged MW in the range of about 25,000 Dalton (Da) or less, typically between 10,000 Da-20,000 Da or any single number within this range, for example 25,250 Da. The MWs disclosed in this invention were determined using gel permeation chromatography (GPC) using NMP with lithium bromide (0.05M) and phosphoric acid (0.05M) as the mobile phase and based on polymethyl methacrylate standards.

Blending of PAE with Acid:

A 1 wt %-100 wt % acid or acid mixture can be used. Solvent for the dilution can be, but not limited to, deionized water, NMP, or methanol. To blend different acids with PAE solutions, acids were added to the PAE solution to a specified loading and allowed to stir for 0.1 min-10 min at ambient temperature. Loading of the acid was calculated by the molar ratio based on the charged amount of DMFDMA during esterification.

### Reaction Work-Up and Sample Preparation:

The PAE solution was precipitated in a large excess of deionized water after the acetal esterification reaction or at a certain time after acid blending. Filtered polymer was washed with water three times and then dried at 80° C. for 24 h under vacuum, yielding a white powder.

### ¹H NMR Measurement

Proton (¹H) NMR spectra were collected by a Bruker Ascend III 500 MHz NMR instrument equipped with a prodigy probe, using deuterated methylsulfoxide (DMSO-d₆) as the solvent. The residual proton signal of DMSO-d₆ (2.50 ppm) was used as the internal standard for chemical shift calibration.

The advantage of this invention is that after the acetal esterification reaction, the subsequent increase in DI of the polymer is reduced if not halted after the addition of a certain acid or acid mixtures at the specified loadings to the PAE solution. Extending the shelf life of the PAE solution substantially improves the feasibility and cost of the manufacturing process of positive-type PSPI precursor polymers.

### DESCRIPTION OF EXPERIMENTS

### Preparation of the Polyamic Ester Solutions P1 and P2 for Examples and Comparative Examples:

To make the PAE solution of 6FDA-6FAPDA, P1, a solution of 10.506 grams (g) 6FAPDA, 62 g NMP and 9.303 g of 6FDA were added to a dry 3-necked flask. The mixture was allowed to stir at 50° C. for 2 h under nitrogen. 0.466 g of 3AP was added and allowed to stir for additional 2 h at 50° C. 5.064 g DMFDMA in NMP (20 wt %) was added to the solution over 15 min. The solution was then held at 50° C. for 20 min before cooling down to the ambient temperature within 10 min. Then, the PAE solution of 6FDA-6FAPDA was ready for the addition of acids for DI stabilization. MW of P1 was 16,500 Da by GPC using NMP with lithium bromide (0.05M) and phosphoric acid (0.05M) as the mobile phase and based on polymethyl methacrylate standards.

A PAE solution of ODPA-PFMB, P2, was prepared using a similar procedure but with a different diamine and dianhydride. Into a dry 3-necked flask was added 5.560 g PFMB, 6.496 g ODPA, and 37.6 g NMP. The MW of P2 was 12,600 Da by GPC using NMP with lithium bromide (0.05M) and phosphoric acid (0.05M) as the mobile phase and based on polymethyl methacrylate standards.

Blending of the Acids with PAE Solutions P1 or P2 and Sample Preparation for Examples and Comparative Examples:

Different acids (diluted to 9 wt % with deionized water, NMP, or methanol) were added to 5.00 g aliquots of PAE solution while stirring at ambient temperature. Loadings of the acid were calculated by the molar ratio based on the charged amount of DMFDMA during esterification. The mixtures and control samples were held at 50° C. for different periods of time. Then 1 mL samples were taken at certain time points, e.g., 2 h, 5 h, or 22 h, from the different solutions. The sample solution was acidified with one drop of acetic acid and precipitated in deionized water. The solid was filtered and washed with water three times, then dried at 80° C. for 24 h under vacuum, yielding a white powder.

### DI Stability of the Redissolved 6FDA-6FAPDA Polymer:

To verify the DI stability of the precipitated polymer, a 6FDA-6FAPDA polymer was dissolved in NMP to make a 20 wt % solution. The polymer solution was held at 50° C. and aliquots were taken at different periods of time. Solution samples were processed, and the DI of the polymer samples were determined by NMR like the other samples.

### Determination of the Degree of Imidization of the 6FDA-6FAPDA Polymers for Examples and Comparative Examples:

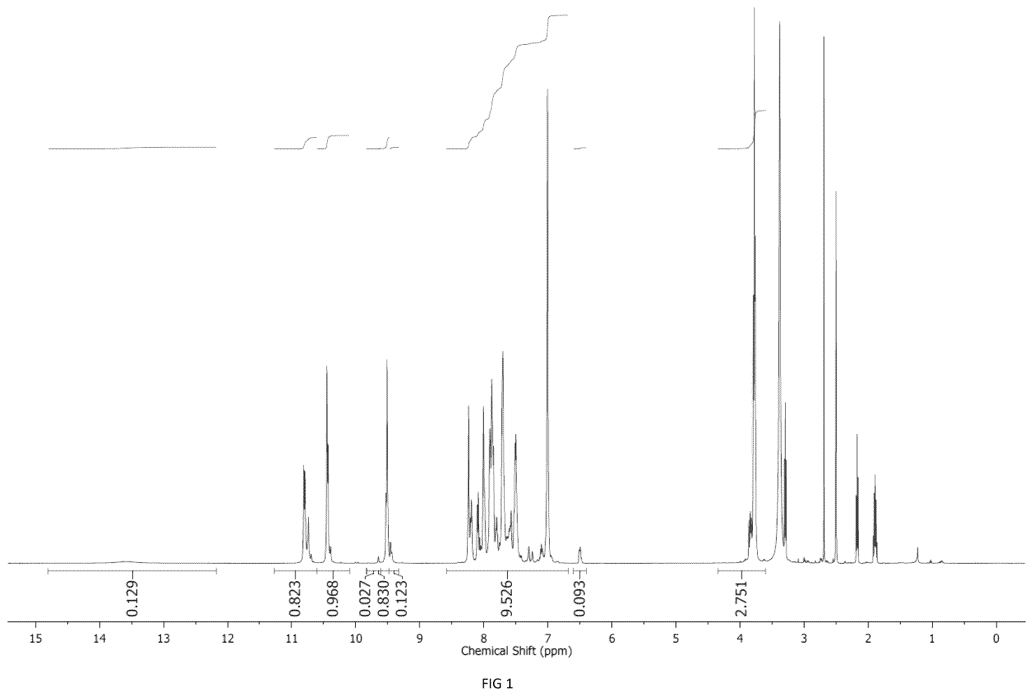

¹H NMR was used to determine the DIs of the polymers. A typical ¹H NMR spectrum for a 6FDA-6FAPDA polymer is shown in FIG. 1. By defining the integration of NMR peaks between 9.47 and 9.85 as Int.A, as well as between 9.61 and 9.85 as Int.B, the DI can be calculated with Equation 1.

$$DI ( 6 FAP - 6 FAPDA ) = \frac{Int . B}{Int . B} \times 83 \% \qquad Eq . 1$$

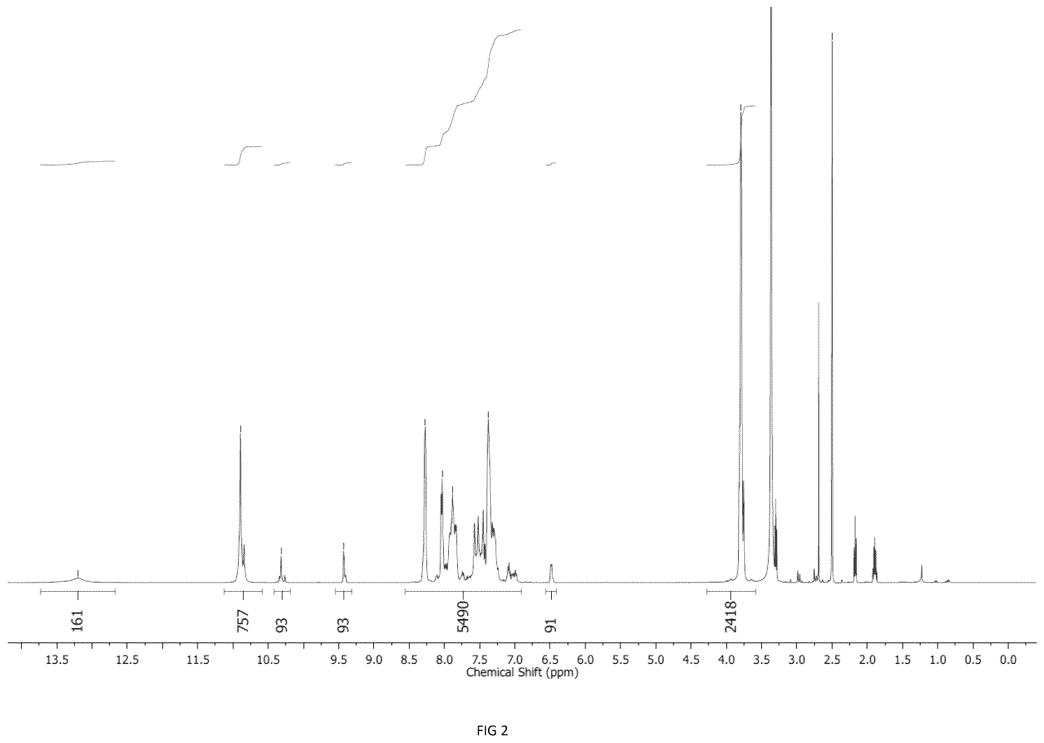

Determination of the Degree of Imidization of the ODPA-PFMB polymers for examples and comparative examples: ¹H NMR was used to determine the DI of the polymers. A typical ¹H NMR spectrum for an ODPA-PFMB polymer is shown in FIG. 2. By defining the integration of NMR peaks between 6.90 and 8.60 as Int.C, as well as between 10.62 and 11.16 as Int.D, the DI can be calculated with Equation 2.

$$DI ( ODPA - PFMB ) = ( 83 - \frac{Int . D}{Int . C} \times 579 ) \% \qquad Eq . 2$$

### EXAMPLES

Using the procedures described above, examples 1-7 and comparative examples 8-10 were prepared as listed in Table 1 along with the DI values of the corresponding polymers under different conditions.

TABLE 1
Examples 1-7 and comparative examples 8-10 as well
as DI test results on 6FDA-6FAPDA polymers.

| | Polymer | HCl | H₂SO₄ | MsOH | AcOH | DI (%, | DI (%, | DI (%, |
|---|---|---|---|---|---|---|---|---|
| Example | Solution | (mol %) | (mol %) | (mol %) | (mol %) | 20 min)^{a} | 2 h)^{b} | 22 h)^{c} |
| Example 1 | P1 | 1.8 | | | | | 3.3 | 4.4 |
| Example 2 | P1 | 7.2 | | | | | 3.3 | 4.6 |
| Example 3 | P1 | 36 | | | | | 4.5 | 11.2 |
| Example 4 | P1 | 96 | | | | | 5.9 | 17.3 |
| Example 5 | P1 | | 7.2 | | | | 3.2 | 3.8 |
| Example 6 | P1 | | 18 | | | | 3.9 | 5.5 |
| Example 7 | P1 | | | 7.2 | | | 3.4 | 3.8 |
| Comparative | P1 | | | | 7.2 | | 6.9 | 32 |
| Example 8 | | | | | | | | |
| Comparative | P1 | | | | | 2.7 | 8.6 | 33 |
| Example 9 | | | | | | | | |
| Comparative | Redissolved | | | | | | 3.5 | 3.5 |
| Example 10 | P1 | | | | | | | |

^{a}Obtained by NMR from the solution sample treated at 50 C. for 20 min.
^{b}Obtained by NMR from the solution sample treated at 50 C. for 2 h.
^{c}Obtained by NMR from the solution sample treated at 50 C. for 22 h.

Examples 1, 2, 3, 4, 5, 6, and 7 demonstrate that with the addition of hydrochloric acid (HCl), sulfuric acid (H₂SO₄), or methanesulfonic acid (MsOH) in the loading range of 1.8-96 mol %, the DI of the treated polymer increased much slower than that of the polymer without acid addition, comparative sample 9. Comparative example 8 demonstrates that with the addition of acetic acid (AcOH) at 7.2 mol % loading, the DI of the treated polymer increased similarly compared to that of the comparative sample 9, the sample without acid addition. Comparative example 10 demonstrates that after the workup process, the polymer in NMP solution is stable for 22 h while being held at 50 C. The redissolved polymer without additional acid treatment, comparative example 10, exhibited no appreciable DI increase during the timeframe evaluated. This further confirmed the efficacy of the acid treatment in stabilizing the DI of 6FDA-6FAPDA polymers and the shelf life extension of the PAE solutions in Examples 1 to 7.

TABLE 2
Examples 11-12 and comparative examples 13-14 as
well as DI test results on ODPA-PFMB polymers.

| | Polymer | H₂SO₄ | H₃PO₄ | DI (%, | DI (%, | DI (%, | DI (%, |
|---|---|---|---|---|---|---|---|
| Example | Solution | (mol %) | (mol %) | 20 min)^{a} | 2 h)^{b} | 5 h)^{c} | 22 h)^{d} |
| Example 11 | P2 | 7.2 | | | 7.4 | 7.8 | 8.2 |
| Example 12 | P2 | 18 | | | 7.8 | 8.2 | 9.3 |
| Comparative | P2 | | 7.2 | | 21 | 29 | 44 |
| Example 13 | | | | | | | |
| Comparative | P2 | | | 7.3 | 17 | 23 | 41 |
| Example 14 | | | | | | | |

^{a}Obtained by NMR from the solution sample treated at 50 C. for 20 min.
^{b}Obtained by NMR from the solution sample treated at 50 C. for 2 h.
^{c}Obtained by NMR from the solution sample treated at 50 C. for 5 h.
^{d}Obtained by NMR from the solution sample treated at 50 C. for 22 h.

Examples 11 and 12 demonstrate that with the addition of H₂SO₄ in the loading range of 7.2-18 mol %, the DI of the treated polymer increased much slower than that of comparative sample 14, the sample without acid addition. Comparative example 13 demonstrates that with the addition of phosphoric acid (H₃PO₄) at 7.2 mol % loading, the DI of the treated polymer increased similarly compared to that of comparative sample 9, the sample without acid addition. This further confirmed the efficacy of the acid treatment on the stabilization of the DI of ODPA-PFMB polymers and the shelf life extension of the PAE solution.

To the extent that the term “includes” or “including” is used in the specification or the claims, it is intended to be inclusive in a manner similar to the term “comprising” as that term is interpreted when employed as a transitional word in a claim. “Consisting of” is a term applied to a composition containing only recited elements, for example A and B. “Consisting essentially of” is a term applied to a composition containing recited elements, A and B but may additionally contain compounds such as water or solvent. Furthermore, to the extent that the term “or” is employed (e.g., A or B) it is intended to mean “A or B or both.” When “only A or B but not both” is intended, then the term “only A or B but not both” will be employed. Thus, use of the term “or” herein is the inclusive, and not the exclusive use. As used in the specification and the claims, the singular forms “a,” “an,” and “the” include the plural. Finally, where the term “about” is used in conjunction with a number, it is intended to include ±1% of the number. For example, “about 10” may mean from 9 to 11. The term wt % is meant to describe a comparison of the weight of one compound to the weight of the whole composition expressed as a percent. It can also be described as wt. %, or (w/w) %.

As stated above, while the present application has been illustrated by the description of embodiments, and while the embodiments have been described in considerable detail, it is not the intention to restrict or in any way limit the scope of the appended claims to such detail. Additional advantages and modifications will readily appear to those skilled in the art, having the benefit of this application. Therefore, the application, in its broader aspects, is not limited to the specific details and illustrative examples shown. Departures may be made from such details and examples without departing from the spirit or scope of the general inventive concept.

We claim:

1. A method to extend the shelf life of polyamic ester (PAE) solutions prepared from the esterification of a polyamic acid (PAA) in solution with an acetal by slowing down the imidization rate through the addition of an acid or acids that have a pKₐ₍₁₎ less than 2.1 and a loading range between 1 mol %-100 mol % based on the charged amount of acetal.

2. The method of claim 1, wherein the acid is one or a combination of acids that has a pKₐ₍₁₎ less than 1.0.

3. The method of claim 1, wherein the acid is one or a combination of acids that has a pKₐ₍₁₎ less than 0.

4. The method of claim 1, wherein the acid is one or a combination of hydrochloric acid, sulfuric acid, methanesulfonic acid, and trifluoroacetic acid.

5. The method of claim 1, wherein the acid is sulfuric acid.

6. The method of claim 1, wherein the acid has a loading range of 1 mol %-100 mol % based on the charged amount of acetal.

7. The method of claim 1, wherein the acid has a loading range of 1.8 mol %-36 mol % based on the charged amount of acetal.

8. The method of claim 1, wherein the acid has a loading range of 2 mol %-10 mol % based on the charged amount of acetal.

9. The method of claim 1, wherein the PAA is made by a condensation reaction between aromatic dianhydrides and aromatic diamines.

10. The method of claim 9, wherein the aromatic dianhydride includes one or a combination of 4, 4′-(hexafluoroisopropylidene)-diphthalic anhydride (6FDA), 4, 4′-oxydiphthalic anhydride (ODPA), pyromellitic dianhydride (PMDA), 3, 3′, 4, 4′-biphenyltetracarboxylic dianhydride (BPDA), 2,3,3,4-biphenyl tetracarboxylic dianhydride (a-BPDA), 3, 3′, 4, 4′-benzophenonetetracarboxylic dianhydride (BTDA), bis [4-(3,4-dicarboxyphenoxy)phenyl]propane dianhydride (BisADA), 4, 4′-(ethyne-1, 2-diyl) diphthalic anhydride (EDDPA), 3, 3′, 4, 4′-diphenylsulfonetetracarboxylic dianhydride (DSDA), 4, 4′-binaphthyl-1, 1′, 8, 8′-tetracarboxylic dianhydride (BNDA), and 1, 4, 5, 8-naphthalene-tetracarboxylic dianhydride (NDA).

11. The method of claim 10, wherein the aromatic dianhydride is 6FDA or ODPA.

12. The method of claim 9, wherein the aromatic diamine includes one or a combination of 2, 2′-bis(trifluoromethyl)benzidine (PFMB), 2, 2-bis(3-(3-aminobenzoylamino)-4-hydroxyphenyl) hexafluoropropane (6FAPDA), 2, 2-bis(3-amino-4-hydroxyphenyl) hexafluoropropane (6FAP), 2, 2-bis(3-(3-aminobenzoylamino)-4-hydroxyphenyl) hexafluoropropane (6FAPDA), p-phenylenediamine (PDA), 4, 4′-oxydianiline (4,4′-ODA), 3,4′-oxydianiline (3,4′-ODA), 4,4′-methylenebis(2,6-dimethylaniline) (D03), 4,4′-(1,3-phenylenedioxy)dianiline, 4,4′-[[1,1′-Biphenyl]-4,4′-diylbis(oxy)]bis[3-(trifluoromethyl)aniline](6FAPBP), 2,2-bis[4-(4-aminophenoxy)phenyl]hexafluoropropane (HFBAPP), bis(4-aminophenyl) sulfone (BSDA), bis[4-(3-aminophenoxy)phenyl]sulfone (M-BAPS), 2, 4-diaminomesitylene (DAM), 1, 5-naphthalenediamine (DAN), 1, 1′-binaphthalene-5, 5′-diamine (DABN), 3, 5-diethyl-toluene-2, 6-diamine (2, 6-DETDA), 3, 5-diethyl-toluene-2, 4-diamine (2, 4-DETDA), and 4, 4′-(9-fluorenylidene) dianiline (FRDA).

13. A method of claim 12, wherein the aromatic diamine is PFMB or 6FAPDA.

14. The method of claim 1, wherein the PAE has a weight-averaged MW less than 25,000 Da.

15. The method of claim 1, wherein the PAE has a weight-averaged MW in the range of 10,000-20,000 Da.

16. The method of claim 1 where the solvent of the PAE is one or a combination of N-methyl-2-pyrrolidone, gamma-butyrolactone, ethyl lactate, dimethylformamide, dimethylacetamide, dimethyl sulfoxide, m-cresol, propylene glycol methyl ether, or propylene glycol methyl ether acetate.

17. The method of claim 1, wherein the solvent of the PAE is N-methyl-2-pyrrolidone.

18. A positive type photosensitive formulation that is comprised of the acid stabilized PAE solution of claim 1.

19. A cured film prepared from a positive type photosensitive composition covered of claim 18.

20. An electronic device that uses the cured film of claim 19.
